(19) United States
(12) Patent Application Publication
(10) Pub. No.: US 2025/0285909 A1
(43) Pub. Date: Sep. 11, 2025

(54) MEMBER FOR SEMICONDUCTOR MANUFACTURING EQUIPMENT

(71) Applicant: NGK INSULATORS, LTD., Nagoya-City (JP)

(72) Inventors: Masaki ISHIKAWA, Handa-Shi (JP); Tatsuya KUNO, Nagoya-Shi (JP); Taro USAMI, Ginan-Cho (JP); Natsuki HIRATA, Nagoya-Shi (JP); Yusuke OGISO, Nagakute-Shi (JP); Hideaki HASHIMOTO, Nisshin-Shi (JP)

(73) Assignee: NGK INSULATORS, LTD., Nagoya-City (JP)

(21) Appl. No.: 18/829,529

(22) Filed: Sep. 10, 2024

Related U.S. Application Data
(63) Continuation of application No. PCT/JP2024/009127, filed on Mar. 8, 2024.

(51) Int. Cl. H01L 21/687

(52) U.S. Cl. CPC H01L 21/68785; H01L 21/68757

(57) ABSTRACT

A member for a semiconductor manufacturing equipment includes: a ceramic substrate having an upper surface on which a wafer is to be placed, and a lower surface; a plug placement hole that vertically penetrates the ceramic substrate; and a plug embedded in the plug placement hole; wherein the plug is composed of a dense body and has an upper end surface exposed on a side of the upper surface, a lower end surface exposed on a side of the lower surface, and a gas passage extending from an upper end opening provided on the upper end surface, through an inside of the dense body, to a lower end opening provided on the lower end surface, and wherein the gas passage is provided with a reinforcing rib that divides the upper end opening into a plurality of segments.

### CROSS REFERENCE TO RELATED APPLICATIONS

The present invention claims the benefit of priority to International Patent Application PCT/JP2024/009127 filed on Mar. 8, 2024 with the Japanese Patent Office, the entire contents of which are incorporated herein by reference in its entirety.

### FIELD OF THE INVENTION

The present invention relates to a member for a semiconductor manufacturing equipment.

### BACKGROUND OF THE INVENTION

Conventionally, members for semiconductor manufacturing equipment used for holding, temperature control, transporting, or the like of wafers have been known. These types of members for semiconductor manufacturing equipment are also called a wafer placement table, an electrostatic chuck, a susceptor, or the like. Generally, they have the function of applying electrical power for electrostatic adsorption to an internal electrode and adsorbing a wafer using electrostatic force. Some members are known that have a function of controlling the temperature of the wafer by flowing gas between the wafer placement surface and the wafer, which is the object to be adsorbed.

An example of a known member for semiconductor manufacturing equipment includes a ceramic substrate having an upper surface on which a wafer is to be placed, a gas passage portion that vertically penetrates the ceramic substrate, and a conductive base plate bonded to the lower surface of the ceramic substrate. During wafer processing, a cooling gas such as helium gas is introduced to the back surface of the wafer through the gas passage.

In such a member for a semiconductor manufacturing equipment, a large potential difference from the wafer may occur, and discharge (insulation breakdown) may occur between the wafer and the base plate via the gas passage portion. For this reason, various techniques for arranging plugs in a gas passage portion have been studied in order to suppress discharge. Plugs are often composed of porous materials. If there is no plug, for example, when gas molecules are ionized by the application of an RF voltage, the generated electrons are accelerated and collide with other gas molecules, causing a glow discharge and eventually an arc discharge. However, if there is a plug, it suppresses the discharge because the electrons hit the plug before colliding with other gas molecules.

Patent Literature 1 proposes a plug having a gas flow passage section that penetrates in flexion a dense main body portion in the thickness direction. It has also been proposed that at least a portion of the entire length of the gas flow passage section be made porous and insulating.

Patent Literature 2 discloses an electrostatic chuck, comprising a ceramic dielectric substrate having a first main surface on which an object to be attracted is placed and a second main surface opposite to the first main surface; a base plate that supports the ceramic dielectric substrate and has a gas introduction path; and a first porous portion provided between the base plate and the first main surface of the ceramic dielectric substrate and facing the gas introduction path; characterized in that the ceramic dielectric substrate has a first main surface and a first hole portion located between the first main surface and the first porous portion; the first porous portion has a porous portion having a plurality of pores, and a first dense portion that is denser than the porous portion; and configured such that when projected onto a plane perpendicular to a first direction from the base plate to the ceramic dielectric substrate, the first dense portion and the first hole portion overlap, but the porous portion and the first hole portion do not overlap.

Patent Literature 3 discloses an electrostatic chuck, comprising a ceramic dielectric substrate having a first main surface on which an object to be attracted is placed and a second main surface opposite to the first main surface; a base plate that supports the ceramic dielectric substrate and has a gas introduction path; and a first porous portion provided between the base plate and the first main surface of the ceramic dielectric substrate and facing the gas introduction path; characterized in that the first porous portion has a plurality of sparse portions having a plurality of pores, and a dense portion having a density higher than the density of the sparse portion; each of the plurality of sparse portions extends in a first direction from the base plate toward the ceramic dielectric substrate; the dense portion is located among the plurality of sparse portions; the sparse portion has the holes and a wall portion provided among the holes; and in a second direction substantially perpendicular to the first direction, the minimum dimension of the wall portion is smaller than the minimum dimension of the dense portion.

Patent Literature 4 describes an invention that aims to provide a holding device that can control the temperature of an object with high accuracy while reducing the occurrence of abnormal discharge. Specifically, it describes a holding device comprising a ceramic substrate having a first surface that holds an object and a second surface located on the opposite side of the first surface; a base member disposed on the second surface side of the ceramic substrate, the base member having a third surface located on the opposite side of the ceramic substrate; and a bonding material disposed between the ceramic substrate and the base member; wherein (1) a passage is formed in the ceramic substrate and the base member to allow fluid to communicate between an outflow hole provided on the first surface and an inflow hole provided on the third surface, or (2) a passage is formed in the ceramic substrate to enable fluid to communicate between an outflow hole provided on the first surface and an inflow hole provided on the second surface; wherein the passage is provided with a porous ceramic region and the porous ceramic region comprises a sparse region and a dense region having a lower porosity than the sparse region and disposed closer to the first surface than the sparse region.

Patent Literature 5 discloses a wafer placement table in which an insulating first porous portion disposed within the through hole of the ceramic plate, and an insulating second porous portion fitted into a recess provided on the ceramic plate side of the base plate so as to face the first porous portion are provided. The gas supplied to the gas introduction path passes through the second porous portion and the first porous portion, flows into the space between the wafer placement surface and the wafer, and is used to cool the object. It is described that due to the presence of the first porous portion and the second porous portion, it is possible to suppress the occurrence of electrical discharge (arc discharge) caused by plasma upon processing wafers while ensuring the gas flow rate from the gas introduction passage to the wafer placement surface.

### PRIOR ART

### Patent Literature

[Patent Literature 1] Japanese Patent Application Publication No. 2022-119338
[Patent Literature 2] Japanese Patent Application Publication No. 2022-31333
[Patent Literature 3] Japanese Patent Application Publication No. 2019-165194
[Patent Literature 4] Japanese Patent Application Publication No. 2022-176701
[Patent Literature 5] Japanese Patent Application Publication No. 2020-72262

### SUMMARY OF THE INVENTION

As described above, various techniques have been proposed for semiconductor manufacturing equipment members to improve the structure in the vicinity of a plug disposed in a gas passage portion that vertically penetrates a ceramic substrate in order to suppress the electrical discharge that occurs between the wafer and the base plate. However, in wafer processing such as deep etching where the plasma power becomes high, discharges are more likely to occur, and more measures against discharges than ever before are required.

Therefore, it is desirable to develop a new discharge suppression technology. By combining such a new discharge suppression technology with a conventional discharge suppression technology, an even greater discharge suppression effect can be expected. Therefore, an object of one embodiment of the present invention is to provide a member for a semiconductor manufacturing equipment in which a technique for suppressing discharge different from the conventional one is adopted.

The present inventors have made extensive studies to solve the above problem, and have created the present invention as exemplified below.

### Aspect 1

A member for a semiconductor manufacturing equipment, comprising: a ceramic substrate having an upper surface on which a wafer is to be placed, and a lower surface; a plug placement hole that vertically penetrates the ceramic substrate; and a plug embedded in the plug placement hole;
wherein the plug is composed of a dense body and has an upper end surface exposed on a side of the upper surface, a lower end surface exposed on a side of the lower surface, and a gas passage extending from an upper end opening provided on the upper end surface, through an inside of the dense body, to a lower end opening provided on the lower end surface, and
wherein the gas passage is provided with a reinforcing rib that divides the upper end opening into a plurality of segments.

### Aspect 2

The member for a semiconductor manufacturing equipment according to aspect 1, wherein a number of the reinforcing rib provided in each of the gas passage is 1 to 5.

### Aspect 3

The member for a semiconductor manufacturing equipment according to aspect 1 or 2, wherein a major axis Xₘₐₓ of the upper end opening assuming the reinforcing rib is not present is 0.1 mm or more.

### Aspect 4

The member for a semiconductor manufacturing equipment according to any one of aspects 1 to 3, wherein each of the plurality of segments of the upper end opening has a major axis Yₘₐₓ and a minor axis Yₘᵢₙ that satisfy a relationship 0.1≤Yₘᵢₙ/Yₘₐₓ≤0.9.

### Aspect 5

The member for a semiconductor manufacturing equipment according to aspect 4, wherein Yₘₐₓ is 0.01 to 0.5 mm.

### Aspect 6

The member for a semiconductor manufacturing equipment according to any one of aspects 1 to 5, wherein when a coordinate axis is taken in a vertical direction, assuming a coordinate value at the upper end surface of the plug is 0 and a coordinate value at the lower end surface of the plug is H, the reinforcing rib is provided in a direction in which the gas passage extends at least in a coordinate value range from 0 to 0.05×H.

### Aspect 7

The member for a semiconductor manufacturing equipment according to aspect 6, wherein the reinforcing rib is not provided at least in a coordinate value range from more than 0.2×H to 1.0×H.

### Aspect 8

The member for a semiconductor manufacturing equipment according to any one of aspects 1 to 7, wherein in a cross section extending in a vertical direction through a central axis of the plug, assuming the reinforcing rib is not present, the gas passage has a flat cross-sectional shape such that a height D in the vertical direction of the gas passage and a width W in the horizontal direction of the gas passage satisfy a relationship 0.1≤D/W≤0.9.

### Aspect 9

The member for a semiconductor manufacturing equipment according to aspect 8, wherein the height D is 10 to 300 μm.

### Aspect 10

The member for a semiconductor manufacturing equipment according to any one of aspects 1 to 9, wherein a fracture toughness value (KIC) of a portion of the plug composed of the dense body is greater than a fracture toughness value (KIC) of the ceramic substrate.

A member for a semiconductor manufacturing equipment according to one embodiment of the present invention is effective in suppressing discharge occurring between a wafer and a ceramic substrate.

### BRIEF DESCRIPTION OF THE DRAWINGS

FIG. 1-1 is a schematic vertical cross-sectional view of a member for a semiconductor manufacturing equipment according to one embodiment of the present invention.

FIG. 1-2 is a schematic vertical cross-sectional view (in a case where there is a single gas passage) passing through the central axis of a plug provided in a member for a semiconductor manufacturing equipment according to one embodiment of the present invention.

FIG. 1-3 is a schematic plan view of a plug provided in a member for a semiconductor manufacturing equipment according to one embodiment of the present invention (in a case where there are four gas passages).

FIG. 1-4 is a schematic plan view of a ceramic substrate provided in a member for a semiconductor manufacturing equipment according to a first embodiment of the present invention.

FIG. 2 is a schematic vertical cross-sectional view of a member for a semiconductor manufacturing equipment according to another embodiment of the present invention.

FIGS. 3A-3C are manufacturing process diagrams of a member for a semiconductor manufacturing equipment according to an embodiment of the present invention.

### DETAILED DESCRIPTION OF THE INVENTION

Hereinafter, embodiments of the present invention will now be described in detail with reference to the drawings. It should be understood that the present invention is not intended to be limited to the following embodiments, and any change, improvement or the like of the design may be appropriately added based on ordinary knowledge of those skilled in the art without departing from the spirit of the present invention. In addition, as used herein, “upper” and “lower” are used to conveniently express the relative positional relationship when a member for a semiconductor manufacturing equipment is placed on a horizontal surface with the upper surface of ceramic substrate for placing a wafer facing up, and they do not represent any absolute positional relationships. Therefore, depending on the orientation of the member for a semiconductor manufacturing equipment, “upper” and “lower” may become “lower” and “upper”, or “left” and “right”, or “front” and “rear”.

### 1. Configuration of Member for Semiconductor Manufacturing Equipment

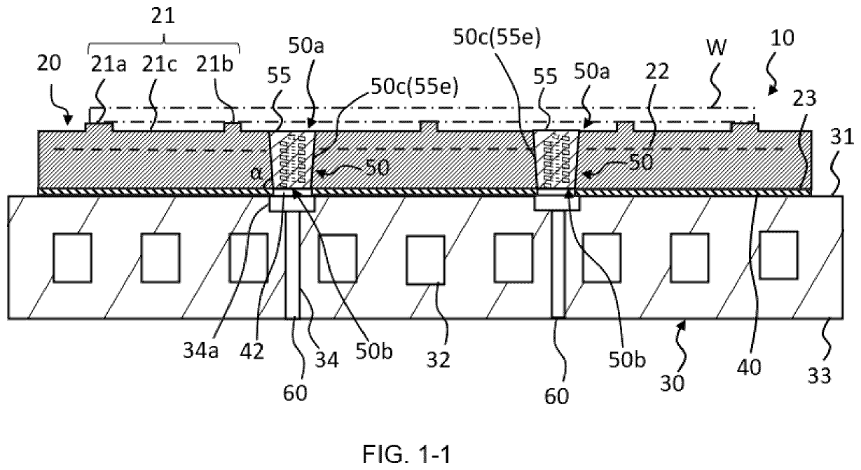

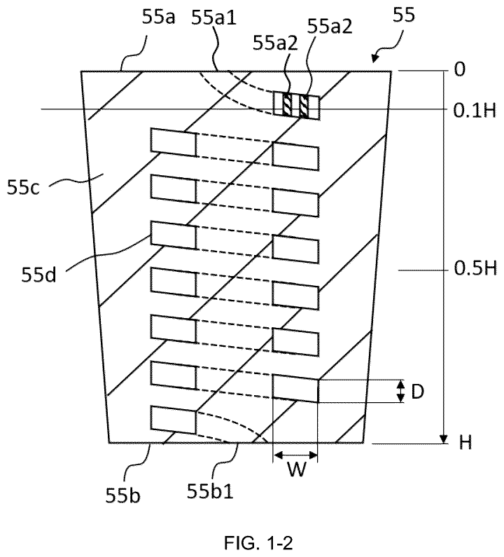

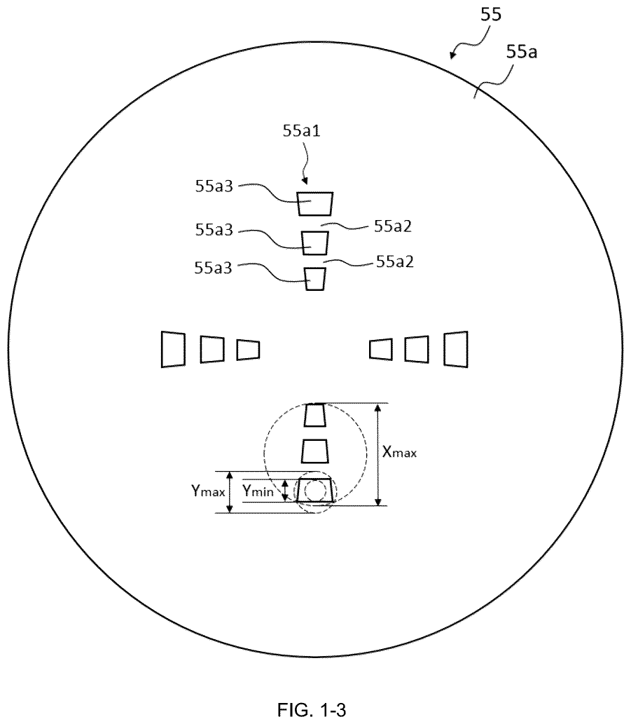

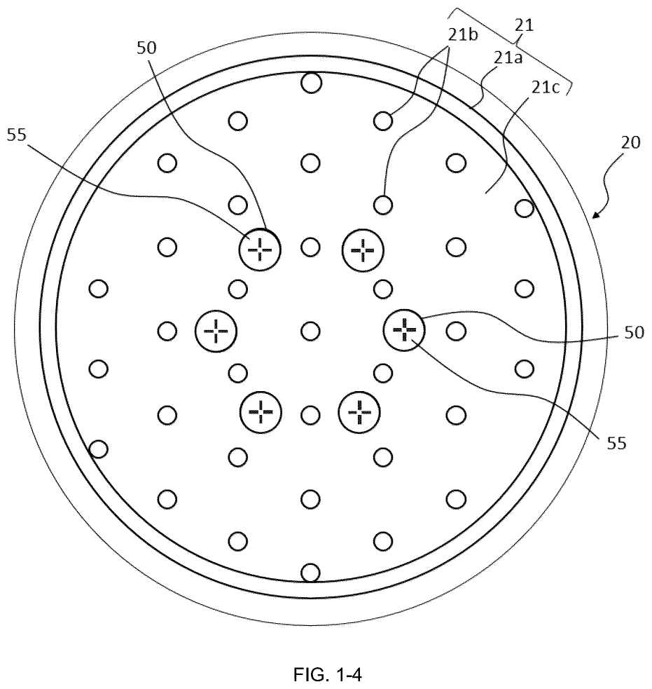

Referring to FIG. 1, a member 10 for a semiconductor manufacturing equipment according to an embodiment of the present invention comprises: a ceramic substrate 20 having an upper surface 21 on which a wafer is to be placed, and a lower surface 23 opposite to the upper surface 21; a plug placement hole 50 that vertically penetrates the ceramic substrate 20; and a plug 55 embedded in the plug placement hole 50. In addition, the member 10 for a semiconductor manufacturing equipment also comprises a base plate 30 bonded to the lower surface 23 of the ceramic substrate 20 via a bonding layer 40, and a gas supply path 60 that passes through the base plate 30 and the bonding layer 40 to supply gas to the plug 55.

### 1-1. Ceramic Substrate

The upper surface 21 of the ceramic substrate 20 has a wafer placement surface on which the wafer W is to be placed. In addition, an electrode 22 is provided inside the ceramic substrate 20. As shown in FIG. 1-1 and FIG. 1-4, on the upper surface 21 of the ceramic substrate 20, an annular seal band 21a is formed along the outer edge, and a plurality of small protrusions 21b are formed on the entire surface inside the seal band 21a. Although the shape of the small protrusion 21b is not limited, it can be, for example, a cylinder, a prism, or the like. It is preferable that the seal band 21a and the small protrusions 21b have the same height, and the height is, for example, 5 to 100 μm, and typically 10 to 30 μm. The electrode 22 is a planar electrode used as an electrostatic electrode, and is connected to an external DC power source via a power supply member (not shown). A low-pass filter may be placed in the middle of the power supply member. The power supply member is electrically insulated from the bonding layer 40 and the base plate 30. When a DC voltage is applied to this electrode 22, the wafer W is adsorbed and fixed to the wafer placement surface (specifically, the upper surface of the seal band 21a and the upper surface of the small protrusion 21b) by electrostatic attraction force, and when the application of the DC voltage is released, the adsorption and fixation of the wafer W to the wafer placement surface is released. In addition, the portion of the upper surface 21 of the ceramic substrate 20 where the seal band 21a and the small protrusions 21b are not provided is referred to as a reference surface 21c.

As the electrode 22, a heater electrode (resistance heating element) may be incorporated instead of or in addition to the electrostatic electrode. In that case, a heater power source is connected to the heater electrode. One layer of electrode may be provided inside the ceramic substrate 20, or two or more layers which are spaced apart from each other may be provided inside the ceramic substrate 20.

The ceramic substrate 20 can be, for example, a circular plate (for example, 300 to 400 mm in diameter) made of ceramics such as alumina sintered body or aluminum nitride sintered body. Although the thickness of the ceramic substrate 20 is not limited, from the viewpoint of increasing the fixing strength of the plug 55, it is preferable that the thickness from an upper opening 50a to a lower opening 50b be 1 mm or more. Further, from the viewpoint of reducing heat transfer of the ceramic substrate 20 and reducing manufacturing costs, the thickness is preferably 5 mm or less, more preferably 3 mm or less, and even more preferably 2 mm or less. Therefore, the thickness from the upper opening 50a to the lower opening 50b is preferably 1 to 5 mm, more preferably 1 to 3 mm, and even more preferably 1 to 2 mm, for example. Here, the thickness from the upper opening 50a to the lower opening 50b means the distance from the center of gravity of the upper opening 50a to the center of gravity of the lower opening 50b. The height of the upper opening 50a is equal to the height of the reference surface 21c of the upper surface 21 of the ceramic substrate 20. The height of the lower opening 50b is equal to the height of the lower surface 23 of the ceramic substrate 20.

### 1-2. Plug Placement Hole

As shown in FIG. 1-1, the plug placement hole 50 is a hole that penetrates the ceramic substrate 20 in the vertical direction from the upper opening 50a to the lower opening 50b. The plug placement hole 50 functions as a gas passage from the lower surface 23 of the ceramic substrate 20 to the reference surface 21c of the upper surface 21. Although only one plug placement hole 50 may be provided, it is preferable to provide a plurality of plug placement holes 50. FIG. 1-4 shows that a plurality of plug placement holes 50 (six in this case) are provided, and a plug 55 is embedded in each of them.

The opening diameter (if the cross section of the plug placement hole is not circular, it means the equivalent circle diameter.) of the plug placement hole 50 in the horizontal direction is not limited, but may be within the range of 1 to 5 mm, typically within the range of 3 to 4 mm, at any height position. The diameter of the plug placement hole 50 may be constant from the lower surface 23 to the upper surface 21 of the ceramic substrate 20, or may vary. In one embodiment, the diameter of the plug placement hole 50 may decrease from top to bottom, and it may have a tapered inner peripheral surface 50c in which the area of the upper opening 50a is larger than the area of the lower opening 50b. If the plug placement hole 50 has such a tapered inner peripheral surface 50a, when embedding the plug 55 into the plug placement hole 50, the plug 55 can easily stop at a predetermined height position of the plug placement hole 50. Therefore, it is possible to obtain an effect that the plug 55 can be embedded in the plug placement hole with high positioning accuracy. Further, while the plug becomes difficult to come out downward, it becomes relatively easy to come out upward, so that the effect of making it easy to replace the plug can be obtained. Furthermore, since the creepage distance becomes longer, an effect of suppressing discharge can also be obtained. The plug placement hole 50 can have, for example, a truncated conical or truncated pyramid space.

The inclination angle α of the inner peripheral surface 50c of the plug placement hole 50 with respect to the lower opening 50b is preferably 70° or more, and more preferably 75° or more, from the viewpoint of increasing the fixing strength of the plug 55, and from the viewpoint of suppressing the volume of the plug 55 from becoming excessively large and securing space for arranging the electrode around it. In addition, it is preferable that the inclination angle α be 87° or less, and more preferable that it is 85° or less, from the viewpoint of improving the positioning accuracy in the height direction of the plug when press-fitting the plug 55 downward into the plug placement hole 50, from the viewpoint of making it easy to replace the plug 55, and from the viewpoint of increasing the creepage distance to prevent discharge. Therefore, the inclination angle α is preferably, for example, 70° to 87°, and more preferably 75° to 85°.

### 1-3. Plug

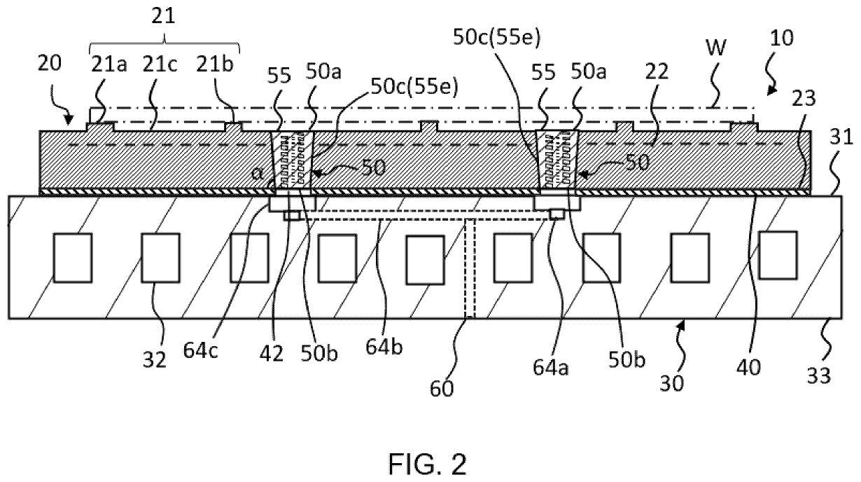

A plug 55 is embedded in the plug placement hole 50. FIG. 1-2 shows a schematic vertical cross-sectional view (in a case where there is a single gas passage) passing through the central axis of the plug 55. FIG. 1-3 shows a schematic plan view of the plug 55 (in a case where there are four gas passages). The plug 55 is composed of a dense body 55c, and has an upper end surface 55a exposed on the side of the upper surface 21 of the ceramic substrate 20, a lower end surface 55b exposed on the side of the lower surface 23 of the ceramic substrate 20, and a gas passage 55d extending from an upper end opening 55a1 provided on the upper end surface 55a through the inside of the dense body 55c to a lower end opening 55b1 provided on the lower end surface 55b.

As used herein, the dense body 55c refers to a portion of the plug 55 that has a porosity of 5% or less. The partial porosity of the plug 55 is measured by the following method. First, the plug 55 is cut so that a cross section passing through the central axis extending in the vertical direction of the plug 55 is exposed. Next, the portion of the cross section to be measured for porosity is observed using a scanning electron microscope (SEM) at a magnification of 3000 times in approximately 2200 μm², and the area ratio of pores confirmed in the portion is calculated. Specifically, by analyzing the SEM image, a threshold value is determined from the luminance distribution of luminance data of pixels in the image using a discriminant analysis method (Otsu's binarization). Thereafter, each pixel in the image is binarized into solid portions and pore portions based on the determined threshold value, and the area of the solid portions and the area of the pore portions are calculated. Then, the ratio of the area of the pores to the total area (the total area of the solid portions and the pore portions) is determined, and this is taken as the porosity of this portion to be measured.

In one embodiment, gas flowing in from the lower end opening 55b1 provided on the lower end surface 55b of the plug 55 can flow through the gas passage 55d provided inside the dense body 55c, and can flow out from the upper end opening 55a1 provided on the upper end surface 55a of the plug 55. In one plug 55, only one gas passage 55d may be provided, or two or more gas passages 55d may be provided. In order to ensure a sufficient gas flow rate, it is preferable that one plug 55 be provided with 2 to 9 gas passages 55d, and more preferably 6 to 9 gas passages 55d. For the sake of simplicity, only one gas passage 55d is shown in FIG. 1-2. FIG. 1-3 shows upper end openings 55a1 which serve as the outlet of the four gas passages 55d. The gas passage 55d may be constructed of a straight line, a curved line, or a combination of both. From the viewpoint of suppressing discharge, it is preferable to configure the gas passage 55d in a shape such that the length of the gas passage is longer than the vertical length of the plug 55, for example, a curved shape such as a spiral or zigzag shape.

The gas passage 55d may be hollow, but at least a part thereof may be porous as long as gas flow is allowed. When at least a part of the gas passage 55d is porous, the gas flowing in from the lower end opening 55b1 of the plug 55 flows through the gas passage 55d formed by a large number of continuous pores, and flows out from the upper end opening 55a1 of the plug 55. The outflowing gas is supplied between the wafer W and the ceramic substrate 20. Since three-dimensional (for example, three-dimensional network) continuous pores that exist within the porous material serve as gas passages, the substantial passage length within the gas passage 55d becomes longer compared to the case where the gas passage 55d is hollow, and an effect that electric discharge is less likely to occur can be obtained. It is also possible to further form one or more gas passages within the porous gas passage.

Therefore, the gas passage 55d may be hollow or porous. It is preferable that at least a part of the gas passage 55d is porous. The fact that the gas passage 55d is hollow means that the porosity is 100%. The fact that the gas passage 55d is porous means that the porosity of the gas passage 55d is greater than 5% and less than 100%. When the gas passage 55d is porous, the porosity of the gas passage 55d is preferably large in order to reduce ventilation resistance. Therefore, the porosity of the gas passage 55d is preferably 10% or more, more preferably 40% or more. On the other hand, the porosity of the gas passage 55d is preferably 50% or less in order to lengthen the passage length of the plug 55 and ensure structural strength. Therefore, the porosity of the gas passage 55d is preferably 10% or more and 50% or less, and more preferably 40% or more and 50% or less. The porosity of the gas passage 55d is measured by mercury porosimetry method (JIS R1655: 2003).

During wafer processing, gas molecules present between the wafer W and the ceramic substrate 20 are ionized, and the resulting electrons are accelerated toward the ceramic substrate 20 and may collide with the upper surface 21 of the ceramic substrate 20. Since the higher the gas velocity caused by the colliding electrons is, the more likely it is that a discharge will occur, it is effective to shorten the distance between the wafer W and the ceramic substrate 20 in order to suppress the gas velocity.

However, if chipping occurs near the upper opening 55a1 of the plug 55 and the gas passage 55d is chipped, the vertical distance from the back surface of the wafer W to the surface 55d1 of the gas passage 55d exposed at the upper opening 55a1 may become long. Accordingly, in order to reduce the risk of chipping, it is effective to provide a reinforcing rib 55a2 that divides the upper end opening 55a1 into a plurality of segments 55a3. Since the opening area of each segment 55a3 is smaller than the opening area of the upper end opening 55a1 before the reinforcing rib 55a2 is provided, chipping is less likely to occur.

When the plug 55 has a plurality of gas passages 55d, it is preferable that all of the plurality of gas passages 55d have the reinforcing rib 55a2. Regarding preferred embodiments such as the number of reinforcing rib 55a2, the major axis Xₘₐₓ, the major axis Yₘₐₓ, the minor axis Yₘᵢₙ, the range in which the reinforcing rib is provided, the height D in the vertical direction of the gas passage, and the width W in the horizontal direction of the gas passage, which will be described below, if the plug 55 has a plurality of gas passages 55d, it is preferred that all of the plurality of gas passages 55d satisfy the conditions for those preferred embodiments.

The number of reinforcing rib 55a2 provided in each of the gas passage 55d is preferably 1 to 5, more preferably 1 to 3, and even more preferably 1 to 2, in order to ensure the gas flow rate.

Chipping is likely to occur when the upper end opening 55a1 is large. For this reason, the effect of suppressing chipping by the reinforcing rib 55a2 is particularly large when the major axis Xₘₐₓ of the upper end opening 55a1 assuming the reinforcing rib 55a2 is not present is, for example, 0.1 mm or more, typically 0.5 mm or more, and more typically 1 mm or more. The upper limit of the major axis Xₘₐₓ is not particularly set, but is, for example, 3 mm or less, and typically 2 mm or less. Therefore, the major axis Xₘₐₓ is, for example, 0.1 to 3 mm, typically 0.5 to 3 mm, and more typically 1 to 2 mm. Here, the major axis Xₘₐₓ of the upper end opening 55a1 assuming the reinforcing rib 55a2 is not present refers to the diameter of the smallest circle that can surround the virtual upper end opening 55a1 in a plan view assuming the reinforcing rib 55a2 is not present (see FIG. 1-3).

The smaller the major axis Yₘₐₓ of each segment 55a3 in the upper end opening 55a1 is, the greater the chipping suppression effect is. Specifically, the major axis Yₘₐₓ is preferably 1 mm or less, more preferably 0.7 mm or less, and even more preferably 0.5 mm or less. On the other hand, the larger the major axis Yₘₐₓ of each segment 55a3 at the upper end opening 55a1 is, the easier it is to ensure the flow rate of gas flowing out from each segment 55a3. Specifically, the major axis Yₘₐₓ is preferably 0.01 mm or more, more preferably 0.05 mm or more, and even more preferably 0.1 mm or more. The major axis Yₘₐₓ of each segment 55a3 in the upper end opening 55a1 is, for example, preferably 0.01 to 1 mm, more preferably 0.01 to 0.5 mm, and even more preferably 0.1 to 0.5 mm.

From the viewpoint of ensuring a gas flow rate, it is preferable that the major axis Yₘₐₓ and minor axis Yₘᵢₙ of each of the plurality of segments 55a3 of the upper end opening 55a1 satisfy a relationship 0.1≤Yₘᵢₙ/Yₘₐₓ, and it is more preferable that a relationship 0.5≤Yₘᵢₙ/Yₘₐₓ be satisfied. On the other hand, from the viewpoint of suppressing chipping, it is preferable to satisfy a relationship Yₘᵢₙ/Yₘₐₓ≤0.9, and it is more preferable to satisfy a relationship Yₘᵢₙ/Yₘₐₓ≤0.7. Therefore, for example, it is preferable to satisfy a relationship 0.1≤Yₘᵢₙ/Yₘₐₓ≤0.9. In addition, a relationship 0.1≤Yₘᵢₙ/Yₘₐₓ≤0.7 may be satisfied, or a relationship 0.5≤Yₘᵢₙ/Yₘₐₓ≤0.9 may be satisfied.

Here, the major axis Yₘₐₓ of each segment 55a3 refers to the diameter of the smallest circle that can surround the segment 55a3 in a plan view (see FIG. 1-3), and the minor axis Yₘᵢₙ of each segment 55a3 refers to the diameter of the largest circle that can be surrounded by the segment 55a3 in a plan view (see FIG. 1-3).

There is no particular limitation on the shape of the opening of each segment 55a3. For example, the opening shape may be formed by a straight line, a curved line, or a combination of both. Specifically, the shape may be a quadrangle such as a square, rectangle, trapezoid, or parallelogram. Among these, a quadrangle with an aspect ratio of 0.1 to 0.9 is preferable because it reduces damage to the plug during processing. Here, the aspect ratio refers to the ratio of the length of the shortest side of the quadrangle that defines the opening of the segment 55a3 to the length of the longest side of the quadrangle that defines the opening of the segment 55a3.

In order to enhance the effect of suppressing chipping, it is preferable that the reinforcing rib 55a2 extends to a certain extent in the direction in which the gas flow passage 55d extends. Specifically, when a coordinate axis is taken in the vertical direction and assuming the coordinate value at the upper end surface 55a of the plug 55 is 0 and the coordinate value at the lower end surface 55b is H, it is preferable that the reinforcing rib 55a2 be provided in the direction in which the gas passage 55d extends at least in the coordinate value range from 0 to 0.05×H, and it is more preferable that the reinforcing rib 55a2 be provided in the direction in which the gas passage 55d extends at least in the coordinate value range from 0 to 0.1×H.

On the other hand, if the reinforcing rib 55a2 extends too far in the direction in which the gas flow passage 55d extends, the pressure loss when the gas flows increases. Therefore, from the viewpoint of ensuring the gas flow rate, it is preferable that the reinforcing rib 55a2 be not provided at least in the coordinate value range from more than 0.5×H to 1.0×H, and it is more preferable that the reinforcing rib 55a2 be not provided at least in the coordinate value range from 0.2×H to 1.0×H.

From the viewpoint of ensuring a necessary gas flow rate when supplying the gas between the wafer W and the ceramic substrate 20, it is preferable that the height of the gas flow passage 55d in the vertical direction is large. Specifically, in a cross section extending in the vertical direction through the central axis of plug 55, the vertical height D of gas passage 55d is preferably 10 μm or more, more preferably 100 μm or more, and even more preferably 300 μm or more. However, from the viewpoint of reducing the risk of discharge by ensuring the passage length and from the viewpoint of ensuring the plug strength, it is preferable that the vertical height D of the gas passage 55d be not made excessively large. Specifically, the vertical height D of the gas passage 55d is preferably 300 μm or less, more preferably 200 μm or less, and even more preferably 100 μm or less. Therefore, the vertical height D of the gas passage 55d is, for example, preferably 10 to 300 μm, more preferably 50 to 300 μm, and even more preferably 100 to 200 μm.

In addition, from the viewpoint of reducing the risk of discharge by ensuring the flow path length and from the viewpoint of ensuring the plug strength, it is preferable that, in a cross section extending in the vertical direction through the central axis of the plug, assuming the reinforcing rib 55a2 is not present, the gas passage 55d have a flat cross-sectional shape such that the vertical height D of the gas passage 55d and the horizontal width W of the gas passage 55d satisfy a relationship 0.1≤D/W≤0.9,. It is more preferable that a relationship 0.3≤D/W≤0.8 be satisfied, and it is even more preferable that a relationship 0.5≤D/W≤0.8 be satisfied.

The vertical height D and horizontal width W of the gas passage 55d are measured by the following procedure: First, the plug is cut such that a cross section extending in the vertical direction through the central axis of the plug is exposed. Next, a scanning electron microscope (SEM) is used to select an appropriate magnification from 50 times to 500 times to observe the portion of the gas passage 55d to be measured from the cross section, and the maximum distance between the opposing surfaces of the portion of the gas passage 55d to be measured in the vertical direction is determined as the vertical height D of the portion of the gas passage 55d (see FIG. 1-2). Further, the maximum distance between the opposing surfaces of the portion of the gas passage 55d to be measured in the horizontal direction is defined as the horizontal width W of the portion of the gas passage 55d (see FIG. 1-2).

In order to suppress the occurrence of chipping in the vicinity of the upper end opening 55a1 of the plug 55, it is desirable for the plug 55 to have a large fracture toughness value (KIC). Specifically, the fracture toughness value (KIC) of the portion of the plug 55 composed of the dense body 55c is preferably greater than the fracture toughness value (KIC) of the ceramic substrate 20. Since the processing conditions of a member for a semiconductor manufacturing equipment are often set based on the ceramic substrate 20, if the fracture toughness value (KIC) of the portion of the plug 55 composed of the dense body 55c is greater than the fracture toughness value (KIC) of the ceramic substrate 20, the risk of chipping of the plug 55 is reduced.

The fracture toughness value (KIC) of the portion of the plug 55 composed of the dense body 55c is preferably 2 MPa·m^{1/2} or more, more preferably 3 MPa·m^{1/2} or more, and even more preferably 4 MPa·m^{1/2} or more. No particular upper limit is set for the fracture toughness value (KIC) of the portion of the plug 55 composed of the dense body 55c. However, from the viewpoint of ease of manufacture, it is preferably 13 MPa·m^{1/2} or less, more preferably 12 MPa·m^{1/2} or less, and even more preferably 11 MPa·m^{1/2} m or less. Therefore, the fracture toughness value (KIC) of the portion of the plug 55 composed of the dense body 55c is preferably 2 to 13 MPa·m^{1/2}, more preferably 3 to 12 MPa·m^{1/2}, and even more preferably 4 to 11 MPa·m^{1/2}.

The fracture toughness value (KIC) of the portion of the plug 55 composed of the dense body 55c and that of the ceramic substrate 20 is measured by the following method in accordance with the single edge precracked beam (SEPB) method defined in JIS R1607: 2015.

The material constituting the plug 55 may be an electrically insulating ceramic, and may contain, for example, one or more selected from aluminum oxide, aluminum nitride, silicon dioxide, and zirconia. Quartz is preferable as the silicon dioxide. The plug 55 may be made of only one or two selected from aluminum oxide and aluminum nitride, excluding impurities. In particular, in order to control the fracture toughness value of the portion of the plug 55 composed of the dense body 55c within the above range, it is preferable that the portion of the plug 55 composed of the dense body 55c be made of a ceramic material such as alumina (aluminum oxide).

Moreover, in order to maintain the fixing strength of the plug 55 embedded in the plug placement hole 50, it is preferable that the difference in thermal expansion coefficient between the plug 55 and the ceramic substrate 20 is small. For this reason, it is preferable that the material constituting the plug 55 and the material constituting the ceramic substrate 20 both contain one or more selected from aluminum oxide and aluminum nitride, and it is more preferable that the material compositions be the same.

The height position of the upper end surface 55a of the plug 55 is not limited. Therefore, the height position of the upper end surface 55a of the plug 55 may be the same height as the reference surface 21c of the ceramic substrate 20, or may be a different height. When the upper end surface 55a of the plug 55 is made lower than the reference surface 21c, it is preferable to place it at a lower position within a range of 0.5 mm or less (preferably 0.2 mm or less, more preferably 0.1 mm or less) in order to suppress the occurrence of discharge. When the upper end surface 55a of the plug 55 is made higher than the reference surface 21c, there is no particular restriction as long as it is lower than the upper surface of the protrusion 21b and the outflow of gas from the plug 55 is not hindered.

There is no particular limit to the height position of the lower end surface 55b of the plug 55. Therefore, the height position of the lower end surface 55b of the plug 55 may be the same height as the lower surface 23 of the ceramic substrate 20, or may be a different height. For example, the lower end surface 55b of the plug 55 may protrude downward from the lower surface 23 of the ceramic substrate 20, or the lower end surface 55b of the plug 55 may be located above the lower surface 23 of the ceramic substrate 20.

The outer peripheral surface 55e of the plug 55 and the inner peripheral surface 50c of the plug placement hole 50 may be bonded together with an adhesive, but it is preferable that they fit directly together without using an adhesive. If the two are directly fitted, no gap will be created between the plug 55 and the plug placement hole 50 caused by deterioration due to corrosion or erosion of the adhesive. Therefore, there is an advantage that discharge and falling off of the plug 55 due to deterioration of the adhesive can be suppressed.

Further, as shown in FIG. 1-1, when observing a vertical cross section obtained by cutting the ceramic substrate 20 in the thickness direction, it is preferable that the inner peripheral surface 50c of the plug placement hole 50 be in contact with the outer peripheral surface 55e of the plug 55 in a parallel positional relationship, from the viewpoint of improving the fixing strength of the plug 55. In other words, the outer peripheral surface 55e of the plug 55 has the same inclination angle as the inner peripheral surface 50c of the plug placement hole 50. Therefore, in a preferred embodiment, the plug has an outer shape that is the same as the plug placement hole (for example, a truncated cone or a truncated pyramid). Thereby, the area in which the inner peripheral surface 50c of the plug placement hole 50 contacts the outer peripheral surface 55e of the plug 55 can be increased, and high fixing strength can be obtained.

An example of a direct fitting method is a method of embedding the plug 55 by press-fitting it into the plug placement hole 50. In this case, in order to obtain the desired fixation strength, it is preferable that the cross-sectional diameter in the horizontal direction at any height position of the plug 55 before press-fitting is made slightly larger (for example, by about 5 to 20 μm in equivalent circle diameter) than the horizontal cross-sectional diameter of the plug placement hole 50 located at the same height position. Further, as a direct fitting method, there is also a method in which a male threaded portion provided on the outer peripheral surface 55e of the plug 55 is screwed into a female threaded portion provided on the inner peripheral surface 50c of the plug placement hole 50.

As a method for manufacturing the plug 55 having such a dense body and a gas passage penetrating therethrough, for example, a method of sintering a formed body formed using an additive manufacturing technique such as a 3D printer can be mentioned. The plug 55 may also be formed by mold casting. Details of mold casting are disclosed in, for example, Japanese Patent No. 5458050. In mold casting, a ceramic slurry containing ceramic powder, a solvent, a dispersant, and a gelling agent is injected into a forming space of a mold, and the gelling agent is chemically reacted to turn the ceramic slurry into a gel, thereby forming a formed body in the mold. In mold casting, an outer mold and a core (a mold having the same shape as the gas passage 55d) made of a material with a low melting point such as wax may be used as a mold to form a formed body within the mold, and then the mold may be heated to a temperature above its melting point to melt and remove the mold or burn it off, thereby producing the formed body. Next, a porous raw material is placed in the cavity corresponding to the gas passage 55d of the obtained formed body. Specifically, for example, a raw material in which a pore-forming material such as resin or wax is added to an aggregate such as ceramic powder is made into a slurry or paste by adding a solvent as necessary, and the cavity corresponding to the gas passage 55d of the formed body is filled with the raw material, and finally the whole is fired. By the firing, the pore-forming material in the porous raw material disappears and a porous portion is formed, and the plug 55 in which the main body portion and the porous portion are integrated is obtained.

The porosity of the plug can be controlled, for example, by adjusting the content of the pore-forming material in the raw material composition before the ceramics that constitutes the plug is produced by firing. For example, the amount of the pore-forming material may be reduced or eliminated in order to densify the plug.

### 1-4. Base Plate

The base plate 30 can be, for example, a circular plate (having a diameter the same as or larger than that of the ceramic substrate 20) having good electrical and thermal conductivity. Referring to FIG. 1-1, inside the base plate 30, a refrigerant passage 32 through which refrigerant circulates may be formed. The refrigerant flowing through the refrigerant passage 32 is preferably liquid and preferably electrically insulating. Examples of the electrically insulating liquid include fluorine-based inert liquids. The refrigerant passage 32 can be formed, for example, in a single stroke across the entire base plate 30 from one end (inlet) to the other end (outlet) in a plan view. A supply port and a recovery port of an external refrigerant device (not shown) are connected to the one end and the other end of the refrigerant passage 32, respectively. The refrigerant supplied from the supply port of the external refrigerant device to the one end of the refrigerant passage 32 passes through the refrigerant passage 32 and then returns from the other end of the refrigerant passage 32 to the recovery port of the external refrigerant device, and after the temperature has been adjusted, the refrigerant is again supplied to the one end of the refrigerant passage 32 from the supply port. The base plate 30 is connected to a radio frequency (RF) power source and can also be used as an RF electrode.

As the material constituting the base plate 30, examples include metal materials and composite materials of metal and ceramics. As the metal material, mention can be made to Al, Ti, Mo, W, and alloys thereof. As composite materials of metal and ceramics, mention can be made to metal matrix composites (MMC) and ceramic matrix composites (CMC). As specific examples of such composite materials, mention can be made to materials containing Si, SiC, and Ti (also referred to as SiSiCTi), materials in which porous SiC is impregnated with Al and/or Si, and composite materials of Al₂O₃ and TiC. A material in which a porous SiC body is impregnated with Al is called AlSiC, and a material in which a porous SiC body is impregnated with Si is called SiSiC. It is preferable to select a material for the base plate 30 that has a coefficient of thermal expansion close to that of the material for the ceramic substrate 20. For example, when the ceramic substrate 20 is made of alumina, the base plate is preferably made of SiSiCTi or AlSiC.

### 1-5. Bonding Layer

As shown in FIG. 1-1, the upper surface 31 of the base plate 30 may be bonded to the lower surface 23 of the ceramic substrate 20 via a bonding layer 40. The bonding layer 40 is formed by, for example, TCB (thermal compression bonding). TCB is a known method in which a metal bonding material is sandwiched between two members to be bonded, and the two members are pressure bonded while being heated to a temperature below the solidus temperature of the metal bonding material. The bonding layer 40 can be composed of a metal bonding layer using, for example, an Al—Mg-based bonding material or an Al—Si—Mg-based bonding material. The bonding layer 40 may be a layer formed of solder or a metal brazing material. Furthermore, the bonding layer 40 may be composed of a resin adhesive layer instead of the metal bonding layer. Examples of the material for the resin adhesive layer include silicone resin-based adhesives, epoxy resin-based adhesives, and acrylic resin-based adhesives. In order to improve the uniformity of the thickness of the resin adhesive layer, a spacer (not shown) may be placed between the upper surface 31 of the base plate 30 and the lower surface 23 of the ceramic substrate 20.

The bonding layer 40 has a through hole 42. The through hole 42 is provided at a position facing a large diameter portion 34a of a gas hole 34, which will be described later. The through hole 42 may be provided coaxially with the large diameter portion 34a, and the diameter of the through hole 42 may be made to match the diameter of the large diameter portion 34a. As used herein, “match” includes not only a complete match but also a substantially match (for example, within a tolerance range) (the same applies hereinafter). A plurality of through holes 42 may be provided for one plug 55, and in this case, it is preferable that the plurality of through holes 42 be provided point-symmetrically with respect to the central axis of the plug 55 extending in the vertical direction. Providing a plurality of through holes 42 can reduce the size of each through hole 42 rather than using one large through hole 42, thereby reducing the risk of electrical discharge. Further, by providing a plurality of through holes 42, a necessary gas flow rate can be ensured.

### 1-6. Gas Supply Path

Referring to FIG. 1-1, a gas supply path 60 for supplying gas to the plug 55 through the base plate 30 and the bonding layer 40 has, for example, a through hole 42 that passes through the bonding layer 40 in the vertical direction, and a gas hole 34 that communicates with the through hole 42 and passes through the base plate 30 from the upper surface 31 to the lower surface 33. A large diameter portion 34a may be further provided on the upper surface 31 of the base plate 30 at a position facing the through hole 42. By having the through hole 42 and further the large diameter portion 34a, even if there is a manufacturing error in the plug placement hole 50 and/or the plug 55 when the plug 55 is arranged in the plug placement hole 50, a space that allows the plug 55 to enter is created, so that such a manufacturing error can be absorbed.

There are no particular restrictions on the configuration of the gas supply path 60. For example, like a member 10 for a semiconductor manufacturing equipment according to another embodiment of the present invention shown in FIG. 2, the base plate 30 may be provided with one or more ring portions 64a having a passage extending concentrically with the base plate 30 in a plan view, one or more gas introduction portions 64b that supply the gas introduced from the lower surface 33 of the base plate 30 to the ring portions 64a, and a distribution portion 64c that distributes the gas from the ring portions 64a to each plug 55. In the present embodiment, the upper end of the distribution portion 64c communicates with the through hole 42 of the bonding layer 40. In FIG. 2, the same components as those in the embodiment shown in FIG. 1-1 are given the same reference numerals. The number of gas introduction portions 64b may be smaller than the number of distribution portions 64c, and may be one, for example. In this way, the number of gas pipes connected to the base plate 30 can be made smaller than the number of plugs 55. Other auxiliary passages not shown may also be provided.

### 1-7. Others

A lift pin hole may be provided that penetrates the member 10 for a semiconductor manufacturing equipment. The lift pin hole is a hole through which a lift pin for moving the wafer W up and down with respect to the upper surface 21 of the ceramic substrate 20 is inserted. Lift pin holes are provided, for example, at three locations when the wafer W is supported by three lift pins.

### 2. How to Use a Member for Semiconductor Manufacturing Equipment

Next, a method of using the member 10 for a semiconductor manufacturing equipment configured in this way will be exemplified. First, a wafer W is placed on the upper surface 21 of the ceramic substrate 20 with the member 10 for a semiconductor manufacturing equipment installed in a chamber (not shown). Then, the pressure inside the chamber is reduced with a vacuum pump and adjusted to the desired degree of vacuum, and a voltage is applied to the electrodes 22 of the ceramic substrate 20 to generate electrostatic adsorption force, and the wafer W is adsorbed and fixed to the wafer placement surface (specifically, the upper surface of the seal band 21a or the upper surface of the small protrusion 21b).

Next, the inside of the chamber is set to a reaction gas atmosphere at a predetermined pressure (for example, several tens to several hundreds of Pa), and in this state, a high frequency voltage such as an RF voltage is applied between an upper electrode (not shown) provided on the ceiling of the chamber and the base plate 30 of the member 10 for a semiconductor manufacturing equipment to generate plasma. The surface of the wafer W is processed by the generated plasma. A refrigerant circulates in the refrigerant passage 32 of the base plate 30. Backside gas is introduced into the gas supply path 60 from a gas cylinder (not shown) for the purpose of cooling. A thermally conductive gas (for example, He gas) can be used as the backside gas. The backside gas is supplied to the plurality of the plug placement holes 50 through the gas supply path 60, and is supplied and sealed in the space between the back surface of the wafer W and the reference surface 21c of the wafer placement surface. The presence of this backside gas allows efficient heat conduction between the wafer W and the ceramic substrate 20.

Further, by providing the plug 55 in the plug placement hole 50, electric discharge within the plug placement hole 50 can be suppressed. If there is no plug 55, electrons generated as gas molecules are ionized by the application of RF voltage are accelerated and collide with other gas molecules, causing glow discharge and eventually arc discharge. However, when the plug 55 is present, the electrons hit the plug 55 before colliding with the other gas molecules, so that discharge is suppressed.

### 3. Method for Manufacturing a Member for Semiconductor Manufacturing Equipment

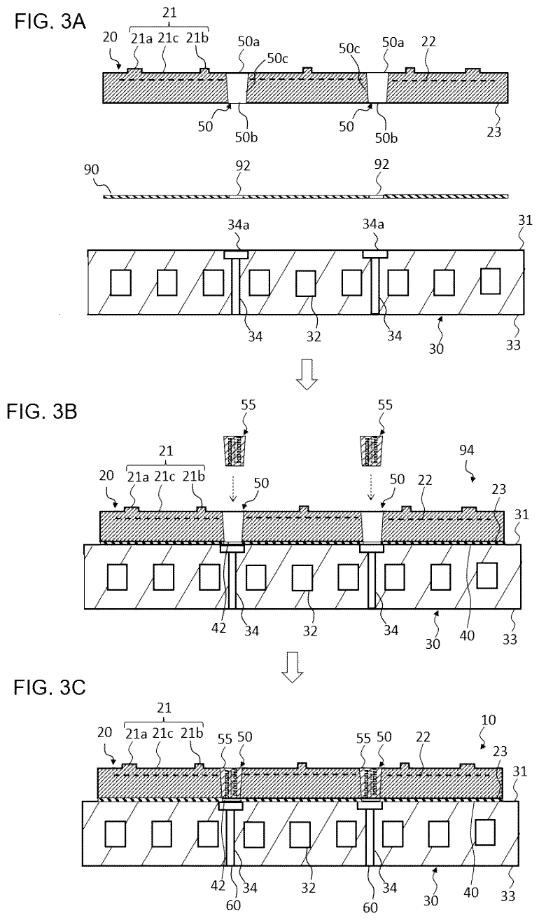

Next, a method for manufacturing the member 10 for a semiconductor manufacturing equipment will be exemplarily described based on FIGS. 3A-3C. First, the ceramic substrate 20, the base plate 30, and the metal bonding material 90 are prepared (FIG. 3A). The ceramic substrate 20 can be prepared by the following procedure. A disk-shaped ceramic sintered plate, which is the source of the ceramic substrate 20, is prepared by hot-pressing and firing a formed body of ceramic powder. The formed body may be produced by stacking a plurality of tape compacts, by a mold casting method, or by compressing ceramic powder. The ceramic sintered plate has an internal electrode 22. Next, a plug placement hole 50 is formed that penetrates the ceramic sintered plate in the vertical direction while avoiding the electrode 22. The plug placement hole 50 can be formed by machining. In addition, a plurality of protrusions 21b and a seal band 21a are formed on the upper surface of the ceramic sintered plate by laser processing or the like. The timing for forming the plurality of protrusions 21b and the seal band 21a may be after the ceramic substrate 20 and the base plate 30 are joined.

The base plate 30 includes a refrigerant passage 32 and a gas hole 34. The gas hole 34 has a large diameter portion 34a facing the upper surface 31. The base plate 30 including the refrigerant passage 32 can be manufactured, for example, by bonding, using a method such as TCB, a plurality of MMC plate members in which a groove or a hole corresponding to the refrigerant passage 32 is formed by machining. The gas holes 34 can be formed by machining the base plate 30 after the refrigerant passage 32 has been formed. The metal bonding material 90 includes a through hole 92 at a position facing the large diameter portion 34a of the gas hole 34. The through hole 92 can be formed by machining.

Subsequently, a metal bonding material 90 is sandwiched between the lower surface 23 of the ceramic substrate 20 and the upper surface 31 of the base plate 30 to form a laminate. At this time, it is preferable to laminate them such that the plug placement hole 50 of the ceramic substrate 20, the through hole 92 of the metal bonding material 90, and the gas hole 34 of the base plate 30 are coaxial. Then, the laminate is pressurized and bonded at a temperature no higher than the solidus temperature of the metal bonding material 90 (for example, the temperature 20° C. lower than the solidus temperature or more and no higher than the solidus temperature), and then returned to room temperature (TCB). Thereby, the metal bonding material 90 and the through hole 92 become the bonding layer 40 and the through hole 42, respectively, and a bonded body 94 in which the ceramic substrate 20 and the base plate 30 are bonded by the bonding layer 40 is obtained (FIG. 3B). The metal bonding material 90 preferably has a thickness of approximately 100 μm (for example, 80 to 240 μm).

Next, a plug 55 having a size and shape that can be fitted into the plug placement hole 50 is prepared (FIG. 3B). The height of the plug 55 is the same as the depth of the plug placement hole 50. Next, the plug 55 is press-fitted into the plug placement hole 50 from the upper opening 50a toward the lower opening 50b of the ceramic substrate 20. Alternatively, a male threaded portion may be formed on the outer peripheral surface 55e of the plug 55, which has been formed in advance by firing or the like, and a female threaded portion may be formed on the inner peripheral surface 50c of the plug placement hole 50, and the plug 55 may be installed by screwing and inserting the plug 55 into the plug placement hole 50 so that the male threaded portion of the plug 55 and the female threaded portion of the plug placement hole 50 are screw fitted together. Thereafter, the member 10 for a semiconductor manufacturing equipment is completed by appropriately going through processes such as adjusting the overall shape (FIG. 3C).

### Description of Reference Numerals

10: Member for semiconductor manufacturing equipment
20: Ceramic substrate
21: Upper surface
21a: Seal band
21b: Protrusion
21c: Reference surface
22: Electrode
23: Lower surface
30: Base plate
31: Upper surface
32: Refrigerant passage
33: Lower surface
34: Gas hole
34a: Large diameter portion
40: Bonding layer
42: Through hole
50: Plug placement hole
50a: Upper opening
50b: Lower opening
50c: Inner peripheral surface
55: Plug
55a: Upper end surface
55a1: Upper end opening
55a2: Reinforcing rib
55a3: Segment
55b: Lower end surface
55b1: Lower end opening
55c: Dense body
55d: Gas passage
55d1: Surface
55e: Outer peripheral surface
60: Gas supply path
64a: Ring portion
64b: Gas introduction portion
64c: Distribution portion
90: Metal bonding material
92: Through hole
94: Bonded body

1. A member for a semiconductor manufacturing equipment, comprising: a ceramic substrate having an upper surface on which a wafer is to be placed, and a lower surface; a plug placement hole that vertically penetrates the ceramic substrate; and a plug embedded in the plug placement hole;
wherein the plug is composed of a dense body and has an upper end surface exposed on a side of the upper surface, a lower end surface exposed on a side of the lower surface, and a gas passage extending from an upper end opening provided on the upper end surface, through an inside of the dense body, to a lower end opening provided on the lower end surface, and
wherein the gas passage is provided with a reinforcing rib that divides the upper end opening into a plurality of segments.

2. The member for a semiconductor manufacturing equipment according to claim 1, wherein a number of the reinforcing rib provided in each of the gas passage is 1 to 5.

3. The member for a semiconductor manufacturing equipment according to claim 1, wherein a major axis Xₘₐₓ of the upper end opening assuming the reinforcing rib is not present is 0.1 mm or more.

4. The member for a semiconductor manufacturing equipment according to claim 1, wherein each of the plurality of segments of the upper end opening has a major axis Yₘₐₓ and a minor axis Yₘᵢₙ that satisfy a relationship 0.1≤Yₘᵢₙ/Yₘₐₓ≤0.9.

5. The member for a semiconductor manufacturing equipment according to claim 4, wherein Yₘₐₓ is 0.01 to 0.5 mm.

6. The member for a semiconductor manufacturing equipment according to claim 1, wherein when a coordinate axis is taken in a vertical direction, assuming a coordinate value at the upper end surface of the plug is 0 and a coordinate value at the lower end surface of the plug is H, the reinforcing rib is provided in a direction in which the gas passage extends at least in a coordinate value range from 0 to 0.05×H.

7. The member for a semiconductor manufacturing equipment according to claim 6, wherein the reinforcing rib is not provided at least in a coordinate value range from more than 0.2×H to 1.0×H.

8. The member for a semiconductor manufacturing equipment according to claim 1, wherein in a cross section extending in a vertical direction through a central axis of the plug, assuming the reinforcing rib is not present, the gas passage has a flat cross-sectional shape such that a height D in the vertical direction of the gas passage and a width W in the horizontal direction of the gas passage satisfy a relationship 0.1≤D/W≤0.9.

9. The member for a semiconductor manufacturing equipment according to claim 8, wherein the height D is 10 to 300 μm.

10. The member for a semiconductor manufacturing equipment according to claim 1, wherein a fracture toughness value (KIC) of a portion of the plug composed of the dense body is greater than a fracture toughness value (KIC) of the ceramic substrate.
